(19) United States
(12) Patent Application Publication
(10) Pub. No.: US 2010/0011274 A1
(43) Pub. Date: Jan. 14, 2010

(54) HYPOTHETICAL FEC DECODER AND SIGNALLING FOR DECODING CONTROL

(75) Inventors: Thomas Stockhammer, Bergen (DE); Michael G. Luby, Berkeley, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/483,191

(22) Filed: Jun. 11, 2009

Related U.S. Application Data
(60) Provisional application No. 61/061,073, filed on Jun. 12, 2008.

(51) Int. Cl. H03M 13/05; G06F 11/10

(52) U.S. Cl. 714/752; 714/E11.032

(57) ABSTRACT

A communication system wherein a transmitter transmits a media stream to a receiver encoded using FEC, comprising at least one hypothetical FEC decoder at the transmitter for decoding the media stream encoded at the transmitter. The transmitter determines what optimization signals to provide the receiver given the outputs of the at least one hypothetical FEC decoder and signals to the receiver those optimization signals. The optimization signals might include slowdown of media consumption signals, indications of variable buffering parameters and/or indications of FEC and source data ordering.

### CROSS-REFERENCE TO RELATED APPLICATIONS

The present disclosure may be related to the following commonly assigned applications/patents.

This application claims priority from U.S. Provisional Patent Application No. 61/061,073 filed Jun. 12, 2008 entitled “Hypothetical FEC Decoder and Early Decoding” which is hereby incorporated by reference, as if set forth in full in this document, for all purposes.

U.S. patent application Ser. No. 11/226,919 (now U.S. Pat. No. 7,233,264) is also incorporated by reference.

U.S. patent application Ser. No. 11/423,391 entitled “Forward Error-Correcting (FEC) Coding and Streaming” is also incorporated by reference.

The respective disclosures of these applications/patents are incorporated herein by reference in their entirety for all purposes.

### FIELD OF THE INVENTION

The present invention relates media serving in general and in particular to transmitters that convey streaming media and decoding signals to receivers to use in a decoding process.

### BACKGROUND OF THE INVENTION

Assume a media server that produces a media packet-stream. The packet stream has associated some strict relative timing with each packet. This exact relative timing needs to be reconstructed at the receiver before the reconstructed packet stream is forwarded to the media client at the receiver. For example, a constant bit rate may need to be maintained.

Along with the packet stream, some parity data may be sent that is generated by an FEC decoder. When an FEC is applied, the encoder stores a certain amount of packets to generate repair data. The collection of the data for which repair data is generated, is referred to as source block.

The amount of data to be stored to generate a source block as well as the duration of the storage may be flexible.

Also, media packets from one source block may be interleaved with packets from other source blocks before the media packets are forwarded to a multiplexer that multiplexes data and FEC data and then transmits them over a channel, which may lose some of the packets. Furthermore, the transmission order of data packets may be changed by the FEC encoding process.

It is assumed that each packet has sufficient information to identify the type, the source block number as well as the position in the source block.

Some examples where such procedures may apply:
MBMS Streaming Delivery with Application Layer FEC [3GPP TS26.346], where a flexible amount of UDP payloads can be inserted in a single source block
Application Layer FEC in IPTV, for example in DVB-IPTV [ETSI TS 102 034 v1.3.1], Annex E
MPE-IFEC in DVB-SH, being used with Reed-Solomon codes or Raptor codes as specified in the document DVB TM- . . .
Link Layer FEC in DVB-RCS as specified in draft ETSI EN XXXXXX.
MediaFlo, TIA-1099 with the use of . . .
Others

At the receiver, an FEC decoder collects source and repair data received from a certain source block and uses this information to reconstruct source packets in a source block.

For the decoder to make use of the generated FEC repair packets to recover from losses the decoder stores the received data packets and the repair packets. Only if the decoder has waited long enough, such that possibly all data packets and all repair packet associated to the one source block have been received, the decoder can ensure that it has made best use of the information being transmitted. In addition, the FEC decoder should make sure that it reconstructs the relative timing of the source data.

To ensure that this happens, the decoder making use of such information requires:
the maximum time it has to buffer packets of a certain source block in the decoder
sufficient storage to ensure that all received source and repair data can be stored.

The transmitter signals to the decoder or the decoder is preconfigured with two values:
initial buffering delay min-buffer-time
maximum buffer size max-buffer-size

The FEC decoder now acts as follows after acquiring the stream: With the reception of the first data packet, it stores the data packet in the FEC decoder for exactly min-buffer-time and takes into account all data received for this source block to attempt to recover the source packets in this source block. Regardless if whether decoding is successful, the FEC decoder releases the first received data packet after min-buffer-time and then maintains the strict timing in the release of further data packets to the media clients. By doing so, the FEC decoder is sure that
it can fulfill the strict timing for all future packets
its max-buffer-size is sufficient to handle all data packets received.

Therefore, it is the task of the sender to ensure that its operations FEC encoding, delay, interleaving and multiplexing is such that the decoder by carrying out the above actions can fulfill the tasks.

The decoder actions from above are referred to as a “hypothetical FEC decoder”, and the transmitter ensures that the transmitted source+FEC stream can be processed by a hypothetical FEC decoder with parameters (min-buffer-time, max-buffer-size) and the outgoing stream has can have the same strict relative timing as the original media stream and no packets have been lost.

### BRIEF SUMMARY OF THE INVENTION

A communication system wherein a transmitter transmits a media stream to a receiver encoded using FEC, comprising at least one hypothetical FEC decoder at the transmitter for decoding the media stream encoded at the transmitter. The transmitter determines what optimization signals to provide the receiver given the outputs of the at least one hypothetical FEC decoder and signals to the receiver those optimization signals. The optimization signals might include slowdown of media consumption signals, indications of variable buffering parameters and/or indications of FEC and source data ordering.

The following detailed description together with the accompanying drawings will provide a better understanding of the nature and advantages of the present invention.

### BRIEF DESCRIPTION OF THE DRAWINGS

FIG. 1 is a block diagram illustrating a conventional communication system.

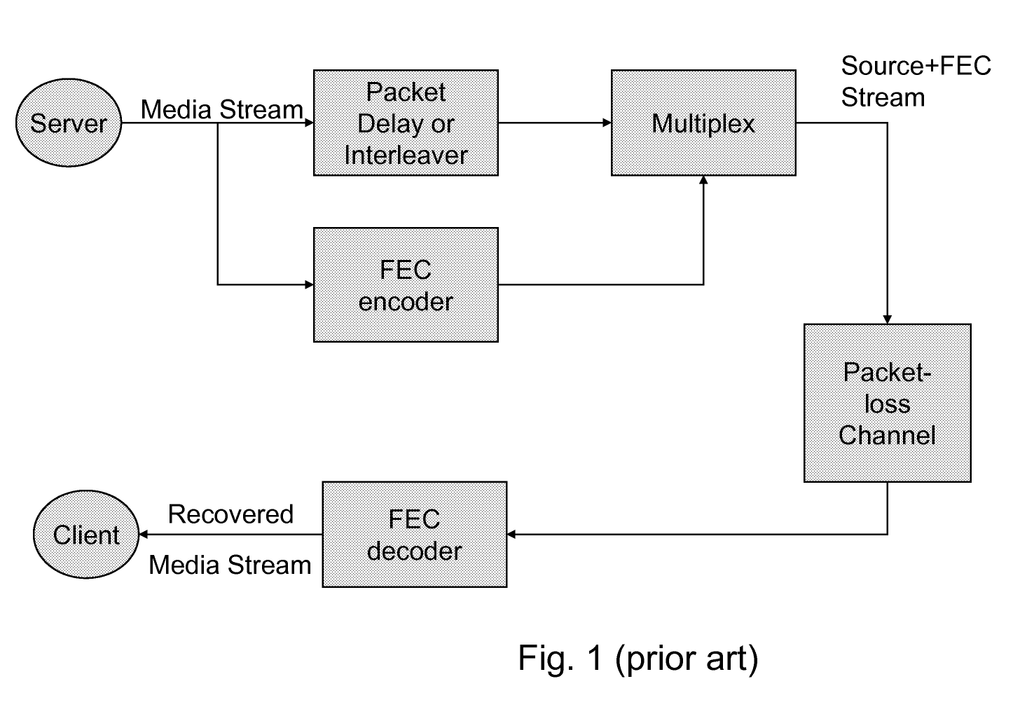

FIG. 2 is a block diagram illustrating a conventional communication system that uses hypothetical decoder.

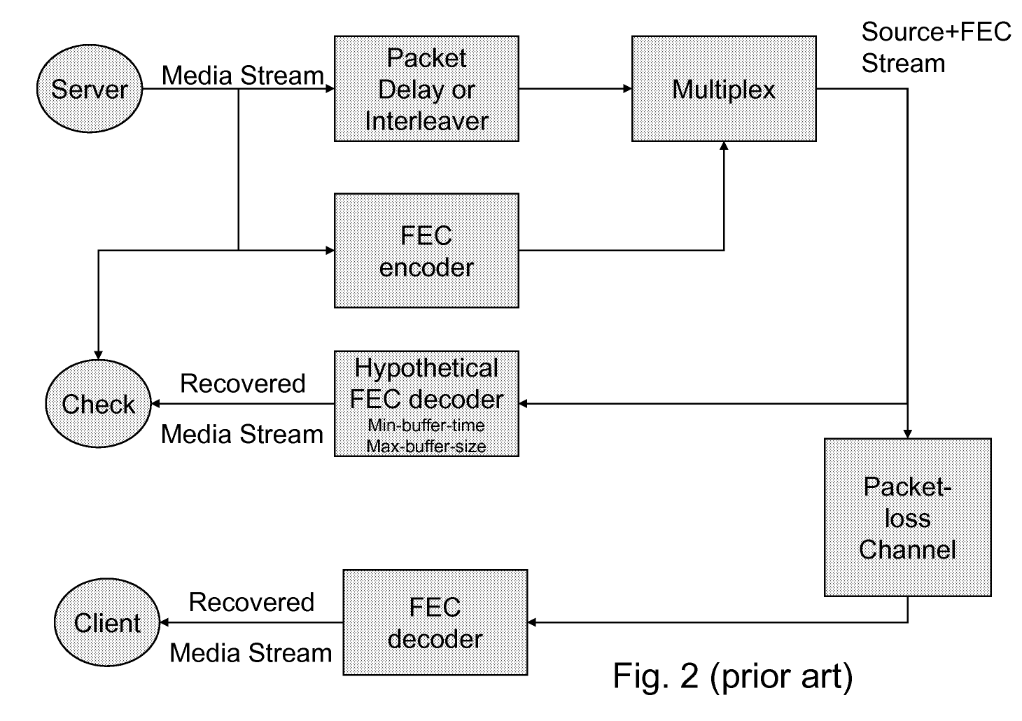

FIG. 3 is a block diagram illustrating a communication system wherein a transmitter uses a plurality of hypothetical decoders to determine decoding optimization signals to provide those to a decoder.

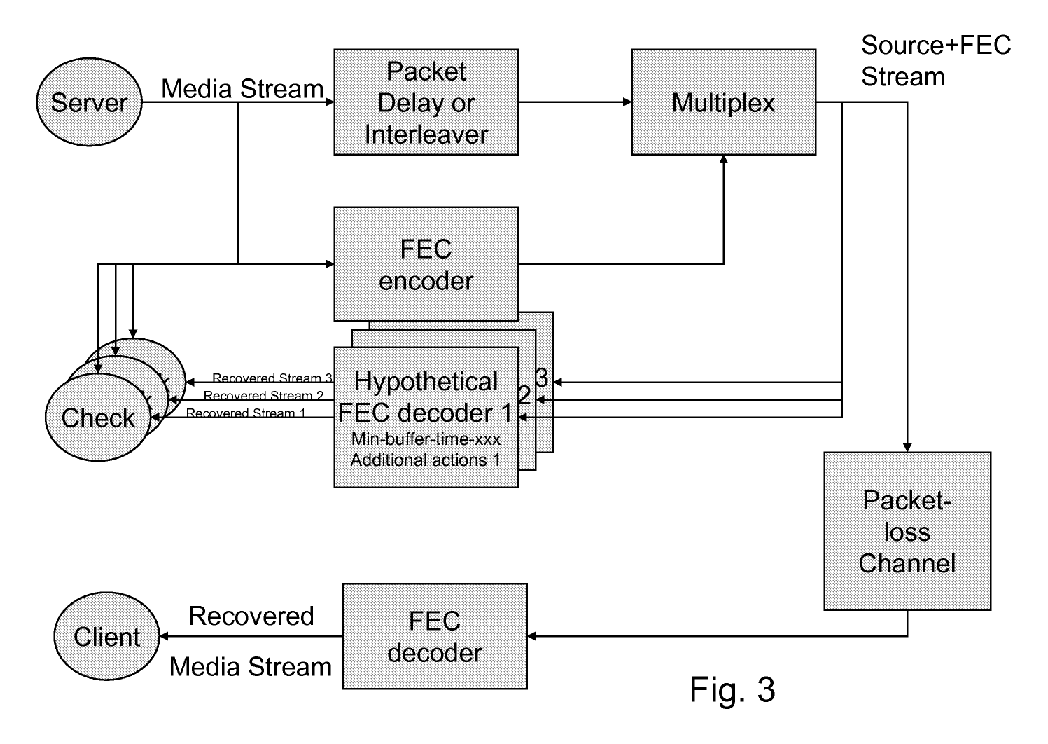

FIG. 4 is a block diagram illustrating DVB-H decoding.

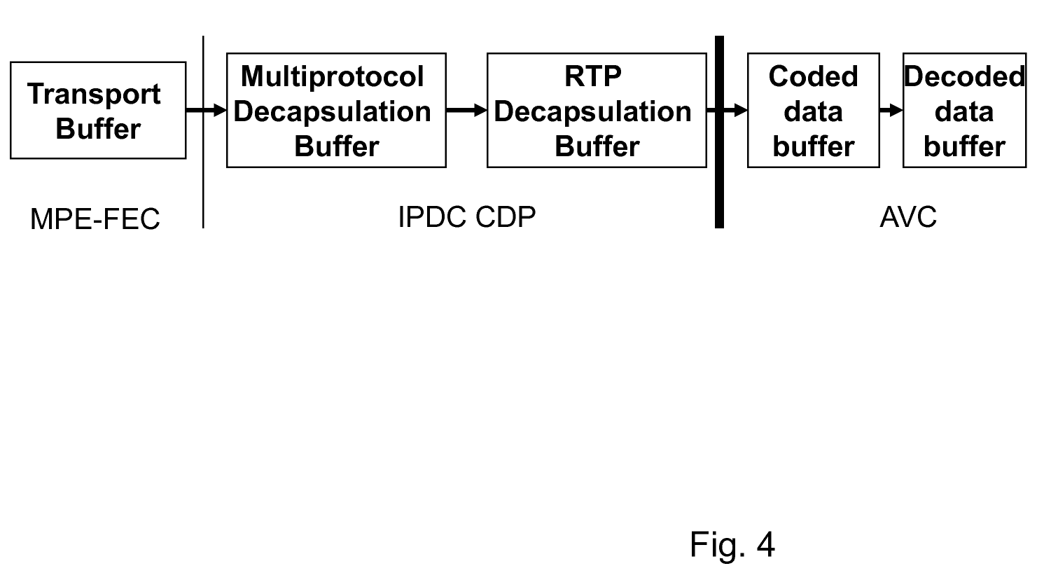

FIG. 5 is a block diagram illustrating DVB-SH decoding.

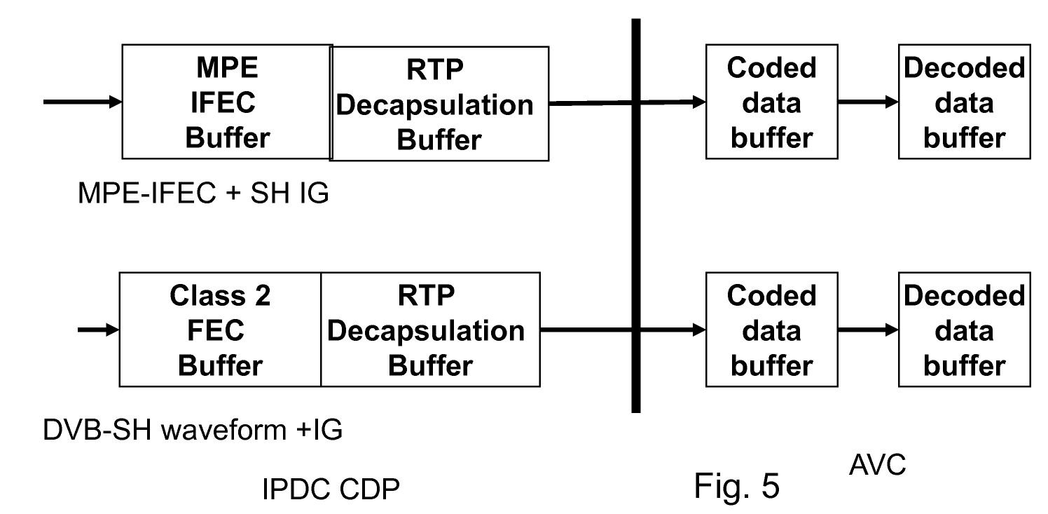

### DETAILED DESCRIPTION OF THE INVENTION

An improved communication system is described herein. In this system, a transmitter uses hypothetical decoders to estimate performance of a decoder and thereby determine decoder optimization parameters, which are then conveyed to the decoder, along with a media stream, and used by the decoder to decode the media stream and play it.

In a conventional “hypothetical FEC decoder” system, a data stream is encoded using forward error correction and at the transmitter, it passes through a hypothetical FEC decoder so that the transmitter will know how it decodes, for example, if the particular stream can be decoded successfully given a minimum buffer time (min-buffer-time) and a maximum buffer size (max-buffer-size). An example of such a hypothetical FEC decoder is specified in 3GPP TS26.346, clause 8.2.2.11.

In operation, once a receiver accesses a new stream (e.g., starts listening to a new channel or the like) and starts to process the stream using its FEC decoder, the receiver needs to wait at least min-buffer-time after the reception of the first source packet before allowing for consumption of the media stream, such as by playback by forwarding the stream to a media client coupled to the receiver or part of the receiver. Therefore, as the media stream needs to be processed by the media decoder as well, the time until the first media, e.g., a video frame or an audio sample, is presented to the user is at least min-buffer-time. This has negative impact on user perception and might be considered not acceptable in many cases, especially in systems where the min-buffer-time is made large to give good diversity.

The decoder may decide to buffer the first packet less than min-buffer-time, in which case channel switching time delays can be reduced, but the decoder may have no idea of the consequences of this decision for the future fluent display. It may be that the decoder cannot make use of the transmitted FEC packets or that source packets cannot released from the FEC decoder in time to ensure that strict timing.

Several solutions for improving performance are described below. Some of these solutions are possible within the above signaling framework, but require actions at the encoder or the decoder. Other solutions add new signaling with adequate defining necessary actions for the decoder. Some aspects also address the co-existence of receivers where some receivers, referred to as legacy receivers, comply to the above prescription on the initial buffering, but other receivers may process the received Source+FEC stream differently by some additional metadata provided along with the stream which is ignored by legacy receivers. A given encoder/decoder might use one of these solutions, or combine solutions.

### Solution 1: Less Initial Buffering and Slowdown of Playout

The decoder may decide to apply some actions to release the first media packet earlier, e.g., by earlier-decoding-time and then applying some means that it can fulfill the min-buffer-time after some time. It may be the case that initially not all data in one source block can be used for recovery. However, for example by slowing down the media payload by some percentage, it can ensure that after some time the remaining time min-buffer-time−earlier-decoding-time is gained by this slowdown and regular playout and continue and all data corresponding to a source block can be from this time on.

However, the encoder may not want that the decoder takes these actions for some content. For example, for certain media content such as music, the slow-down may have an unacceptable perception and the transmitter may prevent the decoder from doing this, or it may specify a maximum slow-down percentage.

For this, the transmitter may add some additional metadata in the setup that specifies:
the minimum initial buffer delay if slow-down is used, min-buffer-time-slowdown
the maximum slow down of the content, max-slowdown-percentage

Only one of the two values might be used. Then, receivers supporting early playout and slowdown then at least wait min-buffer-time-slowdown, if specified, and may slow-down the media playout at most by max-slowdown-percentage.

### Solution 2: Different Min Buffer Time for Random Access Points

In general, a media decoder to start playout a stream requires a random access point in a stream. A random access point may include an Instantaneous Decoder Refresh point in H.264/AVC, and other information necessary to start decoding the stream. The minimal buffer time for all random access points (RAP) may be less than a general min-buffer-time for all packets as specified in setup.

Therefore, an additional signaling may be added that specifies a minimum buffer time min-buffer-time-rap in case any random access point is accessed. This may added to the signaling and a receiver understanding message can use this buffering time min-buffer-time-rap instead of the min-buffer-time. In any case, the encoder must make sure that the transmitted source+FEC stream fulfills this property.

In a further method, the min-buffer-time may not be a generic value which applies for RAP access point, but the metadata may be sent with each RAP in a specific min-buffer-time-rap-x, such that for RAP the initial buffer time may be lower.

Both of the methods may be supported by a sender side reordering of data, for example the source data is delayed in the sender and the FEC data is sent before or interleaved with the source data belonging to this source block.

### Solution 3: Different Min Buffer Time for Different Initial Quality

Furthermore, the source data may be sent in a way that the most important data is sent very late, and less important data within this source block is sent earlier. In this case, several min-buffer-time values may be specified, each with a different quality after switching. Therefore, a single source+FEC stream, or even each random access point may be processed differently at the decoder, and the initial buffer time and the initial quality after switching may be decided by the receiver.

For example a transmitter could signal at the same time
min-buffer-time-low-quality indicating low switching quality, for example that in this case for some time only audio is played and a low quality frame is presented for some time
min-buffer-time-medium-quality indicating some medium quality, e.g. with some reduced playout frame rate initially.
min-buffer-time-no-fec indicating the initial buffer time if no FEC is needed initially, e.g. because the FEC has been sent before the source data.
min-buffer-time the legacy time as indicated above

The receiver may selected the appropriate value according to some user preferences, one the receiving conditions, or other receiver internal information.

These values may again be generic for the entire stream or may be specific for each random access point.

In any case, the encoder should make sure that the stream complies with the indicated values.

### Uses

The above techniques might be used with DVB-H or DVB-SH to provide jitter-free playback. In the case of legacy receivers, the transmitter should just ensure that the time-sliced elementary stream is such that the maximum MDB Buffer size is not exceeded. However, where the receiver can understand signaled min-buffer-time, that can be used to optimize the experience. The transmitter signals a max-buffer-size, which can vary from time to time even over one stream, and a min-buffer-time, which can also vary. These optimization signals can be determined from hypothetical FEC decoders, each of which might operate using a different optimization so that the decoder at the receiver can be told ahead of time what the impacts might be of certain optimization choices. In effect, a transmitter can say to a receiver “if you decode the stream I send you using optimization technique A, you should be fine if you provide for a buffer of size S and you delay consumption by a buffer time T” and transmitter will know the values of S and T for technique A because the transmitter has used its hypothetical FEC decoders for one or more techniques.

This information can be conveyed to the receiver in a Session Description Protocol (SDP) block. An example of a conventional SDP is:

v = 0
o = ghost 2890844526 2890842807 IN IP6
2001:210:1:2:240:96FF:FE25:8EC9
s = 3GPP MBMS Streaming FEC SDP Example
i = Example of MBMS streaming SDP file
u = http://www.infoserver.example.com/ae600
e = ghost@mailserver.example.com
c = IN IP6 FF1E:03AD::7F2E:172A:1E24
t = 3034423619 3042462419
b = AS:15
a = FEC-declaration:0 encoding-id=1
a = FEC-OTI-extension:0 ACAEAA==
a = mbms-repair: 0 min-buffer-time=2600
a = source-filter: incl IN IP6 * 2001:210:1:2:240:96FF:FE25:8EC9
m = application 4006 UDP/MBMS-REPAIR *
b = AS:15
a = FEC:0
a = mbms-flowid: 1=FF1E:03AD::7F2E:172A:1E24/4002,
2 = FF1E:03AD::7F2E:172A:1E24/4003,
3 = FF1E:03AD::7F2E:172A:1E24/4004,
4 = FF1E:03AD::7F2E:172A:1E24/4005,
5 = FF1E:03AD::7F2E:172A:1E24/2269

An SDP to handle decoder optimization signaling might look like this:

SDP Example for Solution 1: slowdown of media playout

v = 0
o = ghost 2890844526 2890842807 IN IP6
2001:210:1:2:240:96FF:FE25:8EC9
s = 3GPP MBMS Streaming FEC SDP Example
i = Example of MBMS streaming SDP file
u = http://www.infoserver.example.com/ae600
e = ghost@mailserver.example.com
c = IN IP6 FF1E:03AD::7F2E:172A:1E24
t = 3034423619 3042462419
b = AS:15
a = FEC-declaration:0 encoding-id=1
a = FEC-OTI-extension:0 ACAEAA==
a = mbms-repair: 0 min-buffer-time=2600
a = mbms-repair: 0 min-buffer-time-slowdown=1300
max-slowdown-percentage=10
a = source-filter: incl IN IP6 * 2001:210:1:2:240:96FF:FE25:8EC9
m = application 4006 UDP/MBMS-REPAIR *
b = AS:15
a = FEC:0
a = mbms-flowid: 1=FF1E:03AD::7F2E:172A:1E24/4002,
2 = FF1E:03AD::7F2E:172A:1E24/4003,
3 = FF1E:03AD::7F2E:172A:1E24/4004,
4 = FF1E:03AD::7F2E:172A:1E24/4005,
5 = FF1E:03AD::7F2E:172A:1E24/2269

SDP Example for Solution 2: Reduced buffer time for all Random access points

v = 0
o = ghost 2890844526 2890842807 IN IP6
2001:210:1:2:240:96FF:FE25:8EC9
s = 3GPP MBMS Streaming FEC SDP Example
i = Example of MBMS streaming SDP file
u = http://www.infoserver.example.com/ae600
e = ghost@mailserver.example.com
c = IN IP6 FF1E:03AD::7F2E:172A:1E24
t = 3034423619 3042462419
b = AS:15
a = FEC-declaration:0 encoding-id=1
a = FEC-OTI-extension:0 ACAEAA==
a = mbms-repair: 0 min-buffer-time=2600
a = mbms-repair: 0 min-buffer-time-rap=2000
a = source-filter: incl IN IP6 * 2001:210:1:2:240:96FF:FE25:8EC9
m = application 4006 UDP/MBMS-REPAIR *
b = AS:15
a = FEC:0
a = mbms-flowid: 1=FF1E:03AD::7F2E:172A:1E24/4002,
2 = FF1E:03AD::7F2E:172A:1E24/4003,
3 = FF1E:03AD::7F2E:172A:1E24/4004,
4 = FF1E:03AD::7F2E:172A:1E24/4005,
5 = FF1E:03AD::7F2E:172A:1E24/2269

SDP Example for Solution 3: Buffer times for reverse sending order

v = 0
o = ghost 2890844526 2890842807 IN IP6
2001:210:1:2:240:96FF:FE25:8EC9
s = 3GPP MBMS Streaming FEC SDP Example
i = Example of MBMS streaming SDP file
u = http://www.infoserver.example.com/ae600
e = ghost@mailserver.example.com
c = IN IP6 FF1E:03AD::7F2E:172A:1E24
t = 3034423619 3042462419
b = AS:15
a = FEC-declaration:0 encoding-id=1
a = FEC-OTI-extension:0 ACAEAA==
a = mbms-repair: 0 min-buffer-time=4000
a = mbms-repair: 0 min-buffer-time-low-quality=1000
a = mbms-repair: 0 min-buffer-time-medium-quality=2000
a = mbms-repair: 0 min-buffer-time-no-fec=3000
a = source-filter: incl IN IP6 * 2001:210:1:2:240:96FF:FE25:8EC9
m = application 4006 UDP/MBMS-REPAIR *
b = AS:15
a = FEC:0
a = mbms-flowid: 1=FF1E:03AD::7F2E:172A:1E24/4002,
2 = FF1E:03AD::7F2E:172A:1E24/4003,
3 = FF1E:03AD::7F2E:172A:1E24/4004,
4 = FF1E:03AD::7F2E:172A:1E24/4005,
5 = FF1E:03AD::7F2E:172A:1E24/2269

Note that all three solutions support backward-compatibility as the non-understood SDP attributes will be ignored. It may be that these signaled optimization parameters are generated using a hypothetical FEC decoder or otherwise.

In some embodiments, the FEC data is sent before the source data, which can reduce the minimum buffer time, although FEC would not be available right after switching.

If the transmitter signals that early playout is to be permitted, some smaller buffer time might be used (e.g., min-buffer-time-no-FEC<min-buffer-time) to enable faster display after switching. The value for min-buffer-time-no-FEC may be signalled to the receiver or may be receiver implementation specific.

To exploit full FEC capabilities, a receiver should gain some buffer time, namely min-buffer-time−min-buffer-time-no-FEC time, and a reasonable approach would gradually increase the buffer time of the data packets until min-buffer-time is reached.

One way to gain buffer time without delaying the consumption is to reduce the playout speed by some factor and use the rest of the time for FEC data. For example, there could be a slowdown factor applied for a slow-down-time where:

slow-down-time=(min-buffer-time−min-buffer-time-no-fec)/(1−slowdown-factor)

These factors can be included in the SDP, so that one, two or all three optimization signals can be added to improve channel switching without (necessarily) changing the procedures of a legacy receiver that only understands conventional processing. In some variations, there is no backward-compatibility.

Solution 1 allows for a start to decoding earlier and then applying actions, for example media playout slow down to eventually fulfill this later. The signaling is provided to permit this either directly or in a manner that is compatible with legacy solutions or use with conventional media playout slowdown.

Solution 2 addresses a solution to add additional signaling for specific points in the stream, if specific points require less initial buffering than other points in the stream. If the stream is a random access point, then the channel switching time can be reduced. The signaling may be done for all the specific point once, or even individually for each point (which may reduce initial buffering even further).

Solution 3 signals buffering requirements in case the sending order is exchanged such that advanced receivers can benefit from shorter initial buffering.

Further embodiments can be envisioned to one of ordinary skill in the art after reading this disclosure. In other embodiments, combinations or sub-combinations of the above disclosed invention can be advantageously made. The example arrangements of components are shown for purposes of illustration and it should be understood that combinations, additions, re-arrangements, and the like are contemplated in alternative embodiments of the present invention. Thus, while the invention has been described with respect to exemplary embodiments, one skilled in the art will recognize that numerous modifications are possible.

For example, the processes described herein may be implemented using hardware components, software components, and/or any combination thereof. The specification and drawings are, accordingly, to be regarded in an illustrative rather than a restrictive sense. It will, however, be evident that various modifications and changes may be made thereunto without departing from the broader spirit and scope of the invention as set forth in the claims and that the invention is intended to cover all modifications and equivalents within the scope of the following claims.

What is claimed is:

1. A communication system wherein a transmitter transmits a media stream to a receiver encoded using FEC, comprising:
at least one hypothetical FEC decoder at the transmitter for decoding the media stream encoded at the transmitter;
logic, at the transmitter, for determining what optimization signals to provide the receiver given the outputs of the at least one hypothetical FEC decoder; and
logic, at the transmitter, to signal to the receiver the optimization signals.

2. The communication system of claim 1, wherein the optimization signals include slowdown of media consumption.

3. The communication system of claim 1, wherein the optimization signals include indications of variable buffering parameters.

4. The communication system of claim 1, wherein the optimization signals include indications of FEC and source data ordering.
